(19) United States
(12) Patent Application Publication
(10) Pub. No.: US 2016/0314878 A1
(43) Pub. Date: Oct. 27, 2016

(54) COMPOSITE CONDUCTING WIRE, METHOD FOR MANUFACTURING THE SAME, AND APPARATUS FOR MANUFACTURING THE SAME

(71) Applicant: INDUSTRIAL TECHNOLOGY RESEARCH INSTITUTE, Chutung (TW)

(72) Inventors: Yu-Ting LIN, New Taipei City (TW); Kun-Ping HUANG, Miaoli County (TW)

(73) Assignee: INDUSTRIAL TECHNOLOGY RESEARCH INSTITUTE, Chutung (TW)

(21) Appl. No.: 14/754,049

(22) Filed: Jun. 29, 2015

(30) Foreign Application Priority Data
Apr. 21, 2015 (TW) 104112640

(51) Int. Cl. H01B 13/00; H01B 1/02; C23C 16/54; H01B 5/02; C23C 16/511; C23C 16/26; H01J 37/32; H01B 1/04

(52) U.S. Cl. CPC H01B 13/0026; H01J 37/32229; H01J 37/3244; H01J 37/3277; H01B 1/02; H01B 1/04; H01B 5/02; C23C 16/511; C23C 16/26; C23C 16/545

(57) ABSTRACT

An apparatus for manufacturing a composite conducting wire is provided, which includes a gas tube, a hydrocarbon gas source connected to a front part of the gas tube for providing hydrocarbon gas through the gas tube. The apparatus also includes a microwave generator to generate a microwave passing a middle part of the gas tube through a waveguide, such that the hydrocarbon gas in the middle part of the gas tube forms a microwave plasma torch. The apparatus includes a wire guide device to guide a metal wire pass through the middle part of the gas tube. The hydrocarbon gas is decomposed by the microwave plasma torch to form a graphene film wrapping a surface of the metal wire.

### CROSS REFERENCE TO RELATED APPLICATIONS

This Application claims priority of Taiwan Patent Application No. 104112640. filed on Apr. 21, 2015, the entirety of which is incorporated by reference herein.

### TECHNICAL FIELD

The present disclosure relates to an apparatus for manufacturing a composite conducting wire, and also relates to manufacture a graphene film wrapping the surface of the metal wire:

### BACKGROUND

As its relatively low cost and excellent electrical ductivity, copper wire dominates the electrical and electronic related industries such as communications, energy, electric engineering, integrated circuits, and so on, However, the development of copper wire applications have been quite limited for a century long as the manufacturing of high purity copper has been matured. In recent decades, major. interests in wires and cables are focus on the insulation materials, for more resistant to high voltage or high temperature to enameled wires and for more resistant to corrosion to cables.

For the sake of improving the conductivity of copper wire, one current solution is to plate copper wire with silver. The conductivity of silver-plated copper wire increases not only because of the best conductivity of silver in all traditional materials, but also due to skin effect, which magnifies the benefit of silver as the frequency increased. Though it only takes few percent of silver in such wire, the cost of which remains high as silver is one of the noblest metals, thus restricts its application fields.

Graphene is a two-dimensional, single-atomic-thin graphite. It has a remarkable electron mobility and its ideal electrical resistivity even lower than copper's. The experimental results shows that graphene does have a better conductivity in high frequency domain and may due to its electron mobility which is much higher than copper. Besides, it is convenient to grow graphene on copper by chemical vapor deposition (CVD) method, arises the concept of the graphene-plated copper wire as the silver replacement. On the other hand, graphene resists chemical or saline corrosion in a good manner, surpassing almost all kinds of metals except gold.

To fabricate graphene-plate copper wire by CVD, the prevalent art requires high temperature in process, generally around 1000° C., and takes times from several minutes to few hours. Copper engulfed in such a high temperature for that period of time suffers the annealing effect seriously therefor the tensile strength of copper wire recedes (by ˜60% in some cases). In addition, after the graphene coating the wire cannot be forged to regain its strength because graphene or other carbon isomers have no ductility as metals do. Accordingly, there is a need to develop a new process for plating graphene film on the copper wire with low temperature and high yield.

### SUMMARY

This disclosure involves a method and an apparatus to achieve the mentioned purposes by a plasma-based process.

One embodiment of the disclosure provides an apparatus for manufacturing a composite conducting wire, specifically graphene-plated copper wire. The apparatus includes a gas tube, a hydrocarbon gas source connected to the front end of the gas tube, a microwave generator to generate a microwave passing the middle part of the gas tube to form a microwave plasma torch, and a set of wire guide device to guide a metal wire pass through the middle part of the gas tube. The hydrocarbon gas is decomposed by the microwave plasma torch and forms a graphene film, wrapping a surface on the metal wire.

One embodiment of the disclosure provides a method for manufacturing a composite conducting wire, comprising: supplying a microwave and a hydrocarbon gas to form a microwave plasma torch; continuously feeding a metal wire passing through the microwave plasma torch, the hydrocarbon gas is decomposed by the microwave plasma torch forming a graphene film wrapping the surface of the metal wire.

One embodiment of the disclosure provides a composite conducting wire, comprising: a metal wire, a graphene film wrapping the surface of the metal wire, wherein the composite conducting wire and the metal wire have a remaining tensile strength 80-95% of raw.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows an apparatus for manufacturing a composite conducting wire in one embodiment of the disclosure.

FIG. 2 shows a Raman spectroscopy of the graphene film formed on the composite conducting wire in another embodiment of the disclosure.

### DETAILED DESCRIPTION

In the following detailed description, for the purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

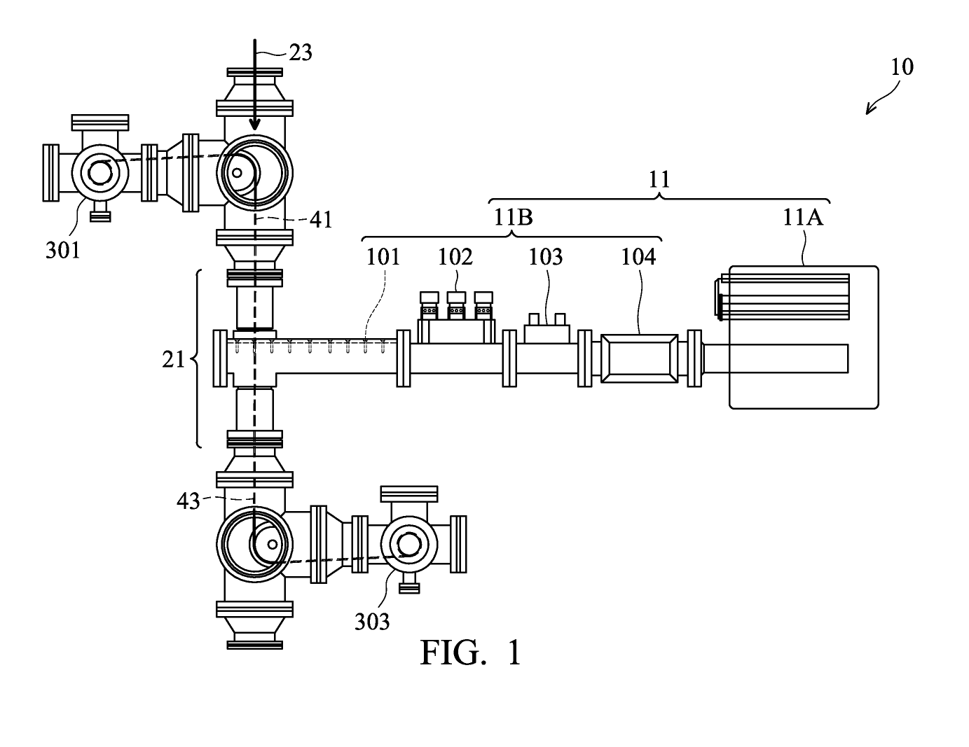

FIG. 1 shows an apparatus 10 for manufacturing a composite conducting wire in one embodiment of the disclosure. A major part of the apparatus is a microwave generator 11 which includes a microwave transmitter module 11A and a waveguide element 11B, a gas tube 21, and wire guide devices (301, 303). The waveguide element 11B includes but not limited to connect to a rectangular coupled plasma waveguide 101, an impedance matching transformer 102, and a directional coupler 103 and loop isolator 104. The rectangular coupled plasma waveguide 101 deposited on the one end of the waveguide element 11B is connected to the middle of the gas tube 21, and the loop isolator 104 deposited on another end of the waveguide element 11B is connected to the microwave transmitter module 11A. The emission band of the microwave transmitter module 11A could be 2.45 GHz, 915 MHz or 5.8 GHz in order to ignite and keep the microwave plasma torch on. For instance, in one embodiment of the disclosure, there is the highest cost benefit ratio for microwave band of 2.45 GHz and in such case the microwave transmitter module 11A is set at a power of 100 W to 1500 W. An overly high microwave power may rise the plasma temperature so as to decline in copper strength. The efficiency for decomposing the hydrocarbon gas may decrease and the yield of graphene may reduce from overly low power of microwave. The microwave transmitter module 11A is set at a power of 200 W to 800 W in one embodiment of the disclosure.

A hydrocarbon gas source 23 is connected to a front end of the gas tube for providing a hydrocarbon gas through the gas tube 21. The hydrocarbon gas includes but not limited to methane, ethane, acetylene, propylene, propane, ethanol, toluene or a combination thereof. It also includes the hydrocarbon compounds formed of gas phase synthesis by the ordinary skill in the art. The microwave plasma torch forms in the intersection of microwave and hydrocarbon gas so as to decompose the hydrocarbon gas to form a graphene. The temperature of microwave plasma torch is set at 500° C. to 1200° C. An overly high temperature of the microwave plasma torch may drop the copper wire strength so as to invalid the microwave plasma torch. An overly low temperature of the microwave plasma torch may cause the bad quality of synthesized graphene or no value. The gas pressure in the gas tube 21 is set at 0.005 Torr to 10 Torr. An overly high gas pressure in the gas tube 21 may rise the plasma temperature so as to melt a copper wire. An overly low gas pressure in the gas tube 21 cause overly low plasma density so as to reduce the yield. In general, the gas pressure in the gas tube 21 is controlled at 0.05 Torr to 0.5 Torr. The hydrocarbon gas source 23 could simultaneously provide the hydrocarbon gas and an inert gas such as argon, nitrogen, helium or the like to adjust the concentration of the hydrocarbon gas so as to increase the graphene film quality in one embodiment of the disclosure. For example, the flow ratio of the inert gas and the hydrocarbon gas is about 0.05:1 to 50:1.

The gas tube 21 could make of non-metal materials such as quartz or any other heat resistant ceramics which include aluminum oxide or zirconium oxide, etc. The direction of gas tube 21 is parallel to the polarization direction of the electric field. In one embodiment of the disclosure, the diameter of the gas tube 21 is of 20 mm to 35 mm or can be 20% to 40% of the diameter for the rectangular coupled plasma waveguide 101. An overly long diameter of the gas tube 21 may not make the plasma energy centralized so as to uneven and reduce the quality of graphene film. If the diameter of the gas tube 21 is overly short, it may reduce the utilization rate. In one embodiment of the disclosure, the length between the center of the gas tube 21 and the end of the rectangular coupled plasma waveguide 101 is equal to half wavelength of the microwave. In such a condition, that would induce plasma to achieve the excellent results

As shown in FIG. 1, the wire guide device includes a feed spool 301 and a collection spool 303 disposed on the two ends of the gas tube 21 respectively to continuously feed the metal wire 41 to pass through the middle part of the gas tube. In one embodiment of the present disclosure, the feed speed of the metal wire 21 is set at 0.3 m/min to 10 m/min. The speed for feeding the metal wire depends on the plating rate of the metal wire.

The tension of the wire depends on wire diameter; it would be controlled below one tenth tensile strength at room temperature. For example, a copper wire with 0.5 mm diameter has the tension of 0.5 N to 5 N. It is easy to fracture for the metal wire in high temperature plasma which may cause from overly high tension. An overly low tension may make the metal wire bend, so as to be not uniform while it is plating. Since the metal wire pass through middle of the gas tube 21, the hydrocarbon gas is decomposed by the microwave plasma torch to form a graphene film wrapping a surface of the metal wire 41 that is so-called composite conducting wire. In one embodiment of the disclosure, the metal wire includes copper, silver, aluminum, gold or a combination thereof. In one embodiment of the disclosure, the metal wire has a diameter of 0.02 mm to 0.55 mm. An overly thick metal wire may make lower efficiency after plating. The metal wire is too fragile to treat from overly thin metal wire. In one embodiment of the disclosure, the composite conducting wire 43 has the graphene layer thickness of 0.005 mm to 1 mm. An overly graphene layer thickness may be useless due to high electric resistance. An overly graphene layer thinness may make lower plating effect because of reducing oxygen resistance. As a composite conducting wire 43 in one embodiment of the disclosure, the radius of the metal wire 41 and the thickness of the graphene layer have the ratio of 10:1 to 100:1. On the other hand, the composite conducting wire 43 and raw metal wire (this is the wire before plating) have the tensile strength ratio of 80:100 to 95:100.

The collection spool 303 spools the composite conducting wire 43 that is produced with the apparatus of the present disclosure. It is worth to note that the microwave plasma torch forms in the intersection between microwave source 11 and hydrogen gas, for example in the middle of gas tube 21. It will not affect the feed spool 301 and collection spool 303. Furthermore, the wire guide device connects to the gas tube 21 which are in the same atmosphere. Generally, they are at same manufacture chamber and will avoid airtight problem happen which is due to the wire guide device and the gas tube in the different pressure chambers.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Example 1

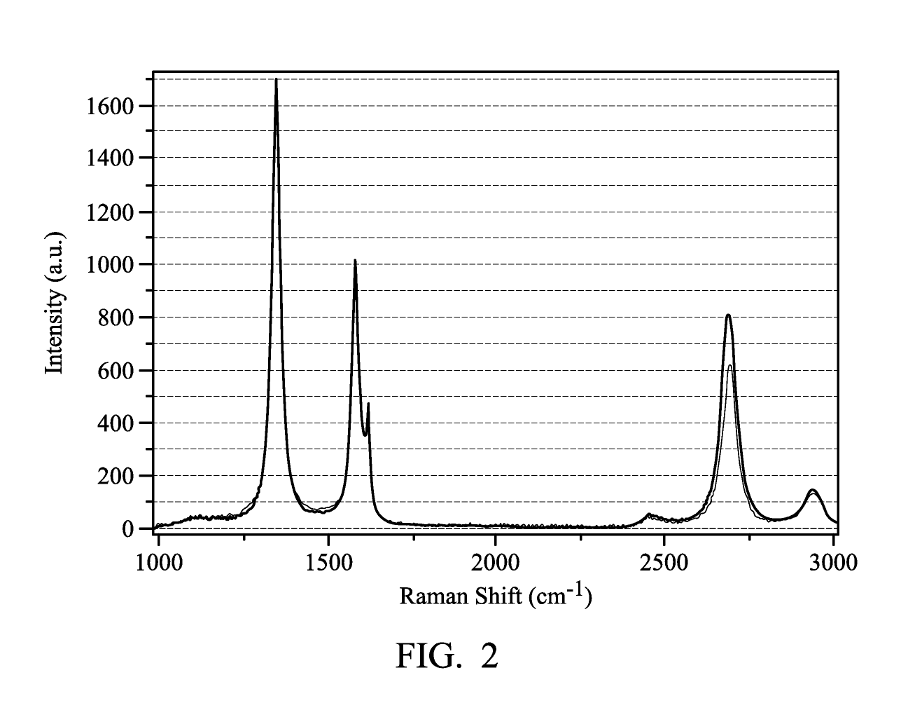

As shown in FIG. 1, a quartz tube served as a gas tube with a diameter of 25 mm and a length of 280 mm. Argon (20 sccm) and methane (10 sccm) were then provided to pass through the quartz tube. A power of microwave generator (commercially available from Richardson Electronics) was set to 200 W for forming a stable plasma torch in the middle of the gas tube. A copper wire (commercially available from standard AWG24) with a conveying rate of 1 m/min was passed through gas tube to form a graphene film (that is composite conducting wire) wrapping a surface of the copper wire. In a Raman spectroscopy as shown in FIG. 2, the graphene film had a characteristic peak 2D of 2680 cm⁻¹ and a graphite characteristic peak G of 1580 cm⁻¹ had similar intensity. It represented that the graphene film had a microstructure of three to four layers. Although from the Raman spectroscopy as shown in FIG. 2, the graphene film had a characteristic peak D of around 1320 cm⁻¹ which indicated there existed a defect, according to the intensity of peak D was lower than half of the intensity of peak D′ (about 1620 cm⁻¹), the signal of the defect peak was from the edge grains of the graphene film rather than the tangled hetero structure of the graphene film itself. The composite conducting wire had a tensile strength of 198 MPa to 210 MPa and was 87-92% of the tensile strength of raw copper wire (228 MPa). On the other hand, the high frequency transmission conductivities of the composite conducting wire in 1000 kHz, 2000 kHz, 3000 kHz, 4000 kHz, and 5000 kHz were higher than those of the raw copper wire of 0.1%, 1.9%, 5.3%, 8.8%, and 10.2% respectively

### Example 2

As shown in FIG. 1, a quartz tube served as a gas tube with a diameter of 25 mm and a length of 280 mm. Argon (20 sccm) and methane (10 sccm) were then provided to pass through the quartz tube. A power of microwave generator (commercially available from Richardson Electronics) was set to 200 W for forming a stable plasma torch in the middle of the gas tube. A copper wire with a 0.254 mm in diameter (commercially available as AWG30) with a conveying rate of 0.2 m/min was passed through gas tube to form a graphene film of 1.0 μm in thickness (that is composite conducting wire) wrapping a surface of the copper wire. The composite conducting wire had a tensile strength of 190 MPa and was 83% of the tensile strength of raw copper wire (247 MPa). On the other hand, the high frequency transmission conductivities of the composite conducting wire in 1000 kHz, 2000 kHz, 3000 kHz, 4000 kHz, and 5000 kHz were higher than those of the raw copper wire of 0.0%, 0.1%, 0.2%, 1.2%, and 3.3% respectively.

### Comparative Example 1

The difference between Comparative Example 1 and Example 1 was to use chemical vapor deposition (CVD) method to deposit several atomic layers thickness of graphene film on copper wire instead of using microwave plasma torch to form a graphene film wrapping a surface of the metal wire. In this comparative example, a copper wire (the same as example 1) had a diameter of 0.511 mm. A composite conducting wire which had graphene on the surface was formed by CVD method. The tensile strength of the composite conducting wire was 145 MPa and also was about 64% of the tensile strength (226 MPa) of original copper wire.

### Comparative Example 2

The difference between Comparative Example 2 and Example 2 was to use chemical vapor deposition (CVD) method to deposit several atomic thickness of graphene film on copper wire instead of using microwave plasma torch to form a graphene film wrapping a surface of the metal wire. In this comparative example, a copper wire (the same as example 2) had a diameter of 0.254 mm. A composite conducting wire which had graphene on the surface was formed by CVD method. The tensile strength of the composite conducting wire was 103 MPa and also was about 45% of the tensile strength (234 MPa) of original copper wire.

According to Examples 1 and 2 and Comparative Examples 1 and 2, the tensile strength of the composite conducting wire which is made from microwave plasma torch is much higher than the tensile strength of the composite conducting wire which is made from conventional CVD process.

It will be apparent to those skilled in the art that various modifications and variations can be made to the disclosed methods and materials. It is intended that the specification and examples be considered as exemplary only, with a true scope of the disclosure being indicated by the following claims and their equivalents.

What is claimed is:

1. An apparatus for manufacturing a composite conducting wire, comprising:
a gas tube;
a hydrocarbon gas source connected to a front end of the gas tube for providing a hydrocarbon gas through the gas tube;
a microwave generator for generating a microwave passing through a middle part of the gas tube through a waveguide, wherein the hydrocarbon gas in the middle part of the gas tube forms a microwave plasma torch; and
a wire guide device for guiding a metal wire pass through the middle part of the gas tube.

2. The apparatus as claimed in claim 1, wherein the hydrocarbon gas provided by the hydrocarbon gas source comprises methane, ethane, acetylene, propylene, propane, ethanol, toluene or a combination thereof.

3. The apparatus as claimed in claim 1, wherein the hydrocarbon gas source simultaneously provides the hydrocarbon gas and an inert gas to control the concentration of the hydrocarbon gas.

4. The apparatus as claimed in claim 1, wherein the wire guide device is connected to the gas tube.

5. A method for manufacturing a composite conducting wire, comprising:
supplying a microwave and a hydrocarbon gas to form a microwave plasma torch;
continuously feeding a metal wire passing through the microwave plasma torch to form a graphene film wrapping a surface of the metal wire.

6. The method as claimed in claim 5, wherein the microwave has a power of 100 Watt to 1500 Watt.

7. The method as claimed in claim 5, further comprising providing an inert gas to adjust the concentration of the hydrocarbon gas.

8. The method as claimed in claim 5, wherein the hydrocarbon gas comprises methane, ethane, acetylene, propylene, propane, ethanol, toluene or a combination thereof.

9. The method as claimed in claim 5, wherein the step of continuously feeding the metal wire has a rate of 0.3 m/min to 10 m/min.

10. A composite conducting wire, comprising:
a metal wire; and
a graphene film wrapping the surface of the metal wire,
wherein the composite conducting wire and the metal wire have a tensile strength ratio of 80:100 to 95:100.

11. The composite conducting wire as claimed in claim 10, wherein the metal wire comprises copper, silver, aluminum, gold or a combination thereof.

12. The composite conducting wire as claimed in claim 10, wherein a radius of the metal wire and a thickness of the graphene film have a ratio of 10:1 to 100:1.
